(19) United States
(12) Patent Application Publication
(10) Pub. No.: US 2024/0312865 A1
(43) Pub. Date: Sep. 19, 2024

(54) METHODS, SYSTEMS, APPARATUS, AND ARTICLES OF MANUFACTURE TO IMPROVE RELIABILITY OF VIAS IN A GLASS SUBSTRATE OF AN INTEGRATED CIRCUIT PACKAGE

(71) Applicant: Intel Corporation, Santa Clara, CA (US)

(72) Inventors: Kyle Arrington, Gilbert, AZ (US); Bohan Shan, Chandler, AZ (US); Haobo Chen, Chandler, AZ (US); Bai Nie, Chandler, AZ (US); Srinivas Pietambaram, Chandler, AZ (US); Gang Duan, Chandler, AZ (US); Ziyin Lin, Chandler, AZ (US); Hongxia Feng, Chandler, AZ (US); Yiqun Bai, Chandler, AZ (US); Xiaoying Guo, Chandler, AZ (US); Dingying Xu, Chandler, AZ (US)

(21) Appl. No.: 18/182,879

(22) Filed: Mar. 13, 2023

(51) Int. Cl. H01L 23/373; H01L 21/48; H01L 23/498

(52) U.S. Cl. CPC H01L 23/3733; H01L 21/486; H01L 23/49827; H01L 23/49866; H01L 23/49877; H01L 23/15

(57) ABSTRACT

Methods, systems, apparatus, and articles of manufacture to improve reliability of vias in a glass substrate of an integrated circuit package are disclosed. An example integrated circuit (IC) package substrate includes a glass substrate, a via extending between first and second surfaces of the glass substrate, and a conductive material provided in the via, the conductive material including gallium and silver.

### FIELD OF THE DISCLOSURE

This disclosure relates generally to integrated circuit packages and, more particularly, to methods, systems, apparatus, and articles of manufacture to improve reliability of vias in a glass substrate of an integrated circuit package.

### BACKGROUND

In many electronic devices, integrated circuit (IC) chips and/or semiconductor dies are connected to larger circuit boards such as motherboards and/or other types of printed circuit boards (PCBs) via a package substrate. Some package substrates include a glass substrate (e.g., a glass core) having one or more vias extending between first and second sides of the glass substrate. Conductive material may be provided in the vias to electrically couple devices (e.g., the IC chips and/or semiconductor dies) to each other and/or to a PCB.

### BRIEF DESCRIPTION OF THE DRAWINGS

FIG. 1 illustrates an example integrated circuit (IC) package on a printed circuit board.

FIG. 2 is a cross-sectional view of an example package substrate that may be implemented in the IC package of FIG. 1.

FIG. 3 is a cross-sectional view of an example glass substrate used to produce the example glass core of FIG. 2.

FIG. 4 illustrates example vias provided in the glass substrate of FIG. 3.

FIG. 5 illustrates an example adhesive layer provided on inner surfaces of the example vias of FIG. 4.

FIG. 6 illustrates a first example conductive material provided in the example vias of FIGS. 4 and/or 5 to produce the example glass core of FIG. 2.

FIG. 7 illustrates a second example conductive material provided in the example vias of FIGS. 4 and/or 5 to produce the example glass core of FIG. 2.

FIG. 8 is a flowchart representative of an example method of manufacturing the example package substrate of FIGS. 1 and/or 2 including the example glass core of FIGS. 2, 6, and/or 7.

FIG. 9 is a top view of a wafer including dies that may be included in an IC package constructed in accordance with teachings disclosed herein.

FIG. 10 is a cross-sectional side view of an IC device that may be included in an IC package constructed in accordance with teachings disclosed herein.

FIG. 11 is a cross-sectional side view of an IC package that may include a glass core, in accordance with teachings disclosed herein.

FIG. 12 is a cross-sectional side view of an IC device assembly that may include an IC package constructed in accordance with teachings disclosed herein.

FIG. 13 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of a semiconductor device (e.g., a transistor), a semiconductor die containing a semiconductor device, and/or an integrated circuit (IC) package containing a semiconductor die, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a bulk region of a base semiconductor substrate (e.g., a semiconductor wafer) than the second component on which the two components are fabricated or otherwise provided. Similarly, unless otherwise stated or implied from the context, a first component within an IC package (e.g., a semiconductor die) is “above” a second component within the IC package when the first component is farther away from a PCB to which the IC package is to be mounted or attached.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real-world imperfections as will be understood by persons of ordinary skill in the art. For example, “approximately” and “about” may indicate such dimensions may be within a tolerance range of +/−10% unless otherwise specified in the below description. As used herein “substantially real time” refers to occurrence in a near instantaneous manner recognizing there may be real world delays for computing time, transmission, etc. Thus, unless otherwise specified, “substantially real time” refers to real time+/−1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “processor circuitry” is defined to include (i) one or more special purpose electrical circuits structured to perform specific operation(s) and including one or more semiconductor-based logic devices (e.g., electrical hardware implemented by one or more transistors), and/or (ii) one or more general purpose semiconductor-based electrical circuits programmable with instructions to perform specific operations and including one or more semiconductor-based logic devices (e.g., electrical hardware implemented by one or more transistors). Examples of processor circuitry include programmable microprocessors, Field Programmable Gate Arrays (FPGAs) that may instantiate instructions, Central Processor Units (CPUs), Graphics Processor Units (GPUs), Digital Signal Processors (DSPs), XPUs, or microcontrollers and integrated circuits such as Application Specific Integrated Circuits (ASICs). For example, an XPU may be implemented by a heterogeneous computing system including multiple types of processor circuitry (e.g., one or more FPGAs, one or more CPUs, one or more GPUs, one or more DSPs, etc., and/or a combination thereof) and application programming interface(s) (API(s)) that may assign computing task(s) to whichever one(s) of the multiple types of processor circuitry is/are best suited to execute the computing task(s).

### DETAILED DESCRIPTION

In many integrated circuit (IC) packages, a die (e.g., a semiconductor die, a silicon die) is mechanically and/or electrically coupled to a substrate (e.g., a package substrate or a separate semiconductor die) via one or more metal interconnects. In some instances, the metal interconnects extend between first and second sides of a glass substrate (e.g., a glass core) within the package substrate. By using laser-assisted etching, crack free, high-density vias (e.g., channels, hollow shapes, through-glass vias (TGVs)) can be provided in the glass substrate. Different process parameters can be adjusted to achieve vias of various shapes and depths for different devices, architectures, processes, and designs in the glass substrate. In some instances, the vias in the glass substrate can be filled with a conductive material (e.g., copper or a different suitable material). In some instances, the vias in the glass substrate can be filled with materials other than metals (e.g., dielectrics, nitrides, oxides, etc.).

In many IC packages including a glass substrate, copper (e.g., copper plating) is provided in the through-glass vias to produce the metal interconnects extending through the glass substrate. However, due to the difference in the coefficient of thermal expansion (CTE) between copper and glass (e.g., 16 parts per million per degree Celsius (ppm/° C.) for copper compared to 3 to 8 ppm/° C. for glass), the use of copper plating in the vias can reduce reliability of the glass substrate during subsequent assembly procedures. For instance, when the glass substrate is exposed to relatively high temperatures (e.g., 300° C. or above) and/or thermal cycling (e.g., during annealing of the copper plating), the copper plating may expand at a greater rate compared to the glass, resulting in fractures, warpage, delamination of the copper plating from the glass, and/or other defects in the glass and/or other surrounding materials. Conversely, such defects may occur when the glass substrate is exposed to relatively low temperatures, thus causing shrinking (e.g., retraction) of the copper plating. In some instances, fracturing of the glass and/or delamination of the copper can reduce reliability of the glass substrate and, thus, may necessitate repair and/or replacement of the glass substrate.

Examples disclosed herein produce example glass substrates including an example conductive material provided in one or more vias extending between first and second sides of the glass substrate, where the conductive material has a CTE less than 16 ppm/° C. In particular, the conductive material includes an example metal material and an example filler material, where a CTE of the filler material is less than a corresponding CTE of the metal material. In examples disclosed herein, the metal material includes one or more of copper, gallium, silver, indium, tin, or zinc. In some examples, the filler material includes one or more of carbon nano tubes, ceramic fillers, diamond particles, metals, clay fillers, or covalent organic frameworks. In some examples, the filler material has a negative CTE (e.g., a CTE less than 0 ppm/° C.). In examples disclosed herein, the CTE of the conductive material can be adjusted by adjusting an amount (e.g., a percent volume, a concentration) of the filler material in the conductive material. For example, the filler material can be between 1 percent volume and 30 percent volume of the conductive material, and the resulting CTE of the conductive material is between 2 ppm/° C. and 16 ppm/° C. In some examples, an adhesive layer (e.g., an adhesion promoter) is provided in the vias prior to the conductive material being provided in the vias, where the adhesive layer improves adhesion of the conductive material to inner surfaces (e.g., sidewalls) of the vias.

Advantageously, by reducing a CTE of conductive material provided in vias of a glass substrate, examples disclosed herein reduce a CTE differential between the vias and the glass material of the glass substrate. Accordingly, examples disclosed herein reduce a rate of expansion and/or shrinking of the conductive material when exposed to relatively high or low temperatures, thus reducing likelihood of fracture, warpage, delamination, and/or other defects in the glass substrate. As such, examples disclosed herein improve reliability of the glass substrate and/or the vias during subsequent assembly procedures, and reduce cost by reducing a need for repair and/or replacement of the glass substrate.

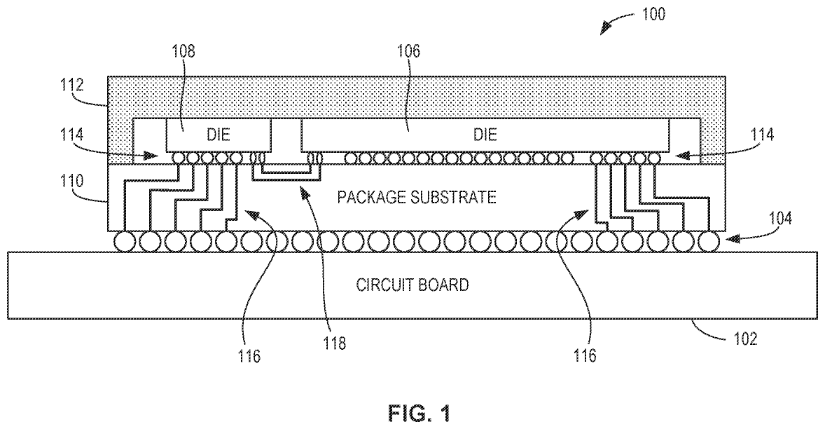

FIG. 1 illustrates an integrated circuit (IC) package 100 electrically coupled to a printed circuit board (PCB) 102. In some examples, the IC package 100 is electrically coupled to the circuit board 102 by first electrical connections 104. The first electrical connections 104 may include pins, pads, bumps, and/or balls to enable the electrical coupling of the IC package 100 to the circuit board 102. In this example, the IC package 100 includes two semiconductor (e.g., silicon) dies 106, 108 that are mounted to a package substrate (e.g., an IC package substrate) 110 and enclosed by a package lid or mold compound 112. While the example IC package 100 of FIG. 1 includes two dies 106, 108, in other examples, the IC package 100 may have fewer or more than two dies.

As shown in the illustrated example, each of the dies 106, 108 is electrically and mechanically coupled to the package substrate 110 via second electrical connections 114. The second electrical connections 114 may include pins, pads, balls, and/or bumps. The second electrical connections 114 between the dies 106, 108 and the package substrate 110 are sometimes referred to as first level interconnects. By contrast, the first electrical connections 104 between the IC package 100 and the circuit board 102 are sometimes referred to as second level interconnects. In some examples, one or both of the dies 106, 108 may be stacked on top of one or more other dies and/or an interposer. In such examples, the dies 106, 108 are coupled to the underlying die and/or interposer through a first set of first level interconnects and the underlying die and/or interposer may be connected to the package substrate 110 via a separate set of first level interconnects associated with the underlying die and/or interposer.

As shown in the illustrated example, the package substrate 110 includes first electrical traces and/or circuit lines (e.g., routing) 116 that electrically connect the first electrical connections 104 to the second electrical connections 114, thereby enabling the electrical coupling of the first and/or second dies 106, 108 with the circuit board 102. Further, in some examples, the package substrate 110 includes second electrical traces and/or circuits (e.g., routing) 118 that electrically connect different ones of the first electrical connections 104 associated with the first and second dies 106, 108, thereby enabling the electrical coupling of the first and second dies 106, 108.

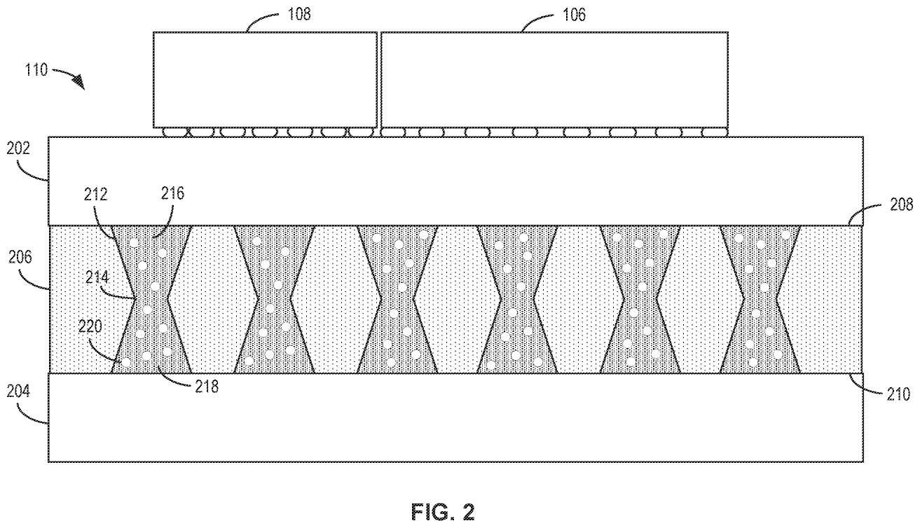

FIG. 2 is a cross-sectional view of an example implementation of the package substrate 110 of FIG. 1. The package substrate 110 of the illustrated example includes first example build-up layers 202, second example build-up layers 204, and an example glass core (e.g., a glass substrate) 206. Specifically, the first build-up layers 202 are provided on a first example surface 208 of the glass core 206 and the second build-up layers 204 are provided on a second example surface 210 of the glass core 206 opposite the first surface 208. In some examples, the build-up layers 202, 204 are provided in an alternating pattern of insulation of dielectric layers and patterned conductive layers providing a plurality of traces between the dielectric layers. In some examples, the traces define signal traces or electrical circuits (e.g., routing, signaling or transmission lines) to transfer signals, information, and/or power between various (e.g., two or more) components (e.g., the dies 106, 108) of an associated IC package (e.g., the IC package 100 of FIG. 1).

Although the glass core 206 of the example package substrate 110 is shown as a central core of the package substrate 110, in some examples, the glass core 206 can be an interposer and/or any other layer of the package substrate 110. For example, the glass core 206 can be used in place of one or more dielectric layers of the package substrate 110. In some examples, the build-up layers 202, 204 can be provided on the glass core 206 using semiconductor manufacturing techniques or processes including, but not limited to, photolithography, integrated circuit microfabrication techniques, wet etching, dry etching, anisotropic etching, spin coating, electroforming or electroplating, laser ablation, sputtering, chemical deposition, plasma deposition, surface modification, injection molding, hot embossing, thermoplastic fusion bonding, low temperature bonding using adhesives, stamping, machining, 3-D printing, laminating, and/or any other processes for manufacture of semiconductor device packages.

In the illustrated example of FIG. 2, the glass core 206 includes example vias (e.g., through-glass vias (TSVs)) 212 extending between the first and second surfaces 208 of the glass core 206. In this example, the vias 212 have an hourglass shape. In particular, a cross-sectional diameter of the vias 212 decreases from the first surface 208 to an example point 214 between the first and second surfaces 208, 210, and the cross-sectional diameter increases from the point 214 to the second surface 210. In this example, the point 214 is approximately a midpoint between the first and second surfaces 208, 210. In some examples, the point 214 is closer to the first surface 208 or the second surface 210. While the vias 212 are hourglass-shaped in this example, the vias 212 can have a different shape (e.g., cylindrical) in some examples.

In the illustrated example of FIG. 2, an example conductive material 216 is provided in the vias 212. For example, the conductive material 216 forms conductive pillars (e.g., metal pillars) that provide an electrical path (e.g., an interconnect) between the first and second surfaces 208, 210 of the glass core 206. In the illustrated example, the conductive material 216 includes an example metal material 218 and an example filler material 220 dispersed in (e.g., distributed throughout a volume of) the metal material 218. In some examples, the metal material 218 includes copper. In some examples, the metal material 218 includes gallium, or an alloy including gallium and one or more of indium, tin, zinc, or silver. In some examples, the filler material 220 includes one or more of carbon nano tubes, ceramic fillers, diamond particles, metal, hollow fillers, clay fillers, or covalent organic frameworks (COFs). In some examples, one or more different materials can be used for the metal material 218 and/or the filler material 220. In the illustrated example of FIG. 2, the filler material 220 includes particles having a circular shape and distributed throughout the metal material 218. In some examples, a size, shape, distribution, and/or number of particles of the filler material 220 can be different than the filler material 220 shown in FIG. 2.

In some examples, a CTE of the filler material 220 is less than a CTE of the metal material 218. For example, the metal material 218 can have a CTE of approximately 16 ppm/° C., and the filler material 220 can have a CTE less than 16 ppm/° C. and/or can have a negative CTE (e.g., a CTE less than zero such that the filler material 220 decreases in size as temperature increases). Accordingly, by combining the metal material 218 and the filler material 220 to produce the conductive material 216, the conductive material 216 can have a CTE less than 16 ppm/° C. In some examples, the conductive material 216 can have a CTE that is substantially similar to a CTE of a glass material of the glass core 206 (e.g., between 3 ppm/° C. and 8 ppm/° C.).

Table 1 below illustrates example negative CTE filler materials (e.g., filler materials having a CTE less than zero) that may be included in the conductive material 216. In this example, a first column of Table 1 below includes the example negative CTE filler materials, and a second column of Table 1 below includes example CTEs (in parts per million per Kelvin (ppm/K)) corresponding to the negative CTE filler materials. In some examples, one or more different filler materials may be used as the filler material 220 in the conductive material 216 in addition to or instead of those listed in Table 1 below. In some examples, the filler material 220 can include multiple different types of materials having different CTEs.

TABLE 1
Negative CTE Filler Materials

| Materials | CTE (ppm/K) |
|---|---|
| β-eucryptite | −1 to −6^{b} |
| α-ZrW₂O₈ | −9 |
| β-ZrW₂O₈ | −6 |
| Cd(CN)₂ | −33.5 |
| ReO₃ | −0.5 |
| ReO₃ | −0.7 |
| (HfMg)(WO₄)₃ | −2^{b} |
| Sm_{2.75}C₆₀ | −100^{b} |
| Bi_{0.95}La_{0.05}NiO₃ | −82^{b} |
| Invar (Fe—36Ni) | 0.1-1 |
| Invar (Fe₃Pt) | −6 to −30 |
| Tm₂Fe₁₆Cr | −9^{b} |
| CuO nano particles | −36^{b} |
| Mn₃Cu_{0.53}Ge_{0.47}N | −16 |
| Mn₃Zn_{0.4}Sn_{0.6}N_{0.85}C_{0.15} | −23 |
| Mn₃Zn_{0.5}Sn_{0.5}N_{0.85}C_{0.1}B_{0.05} | −30 |

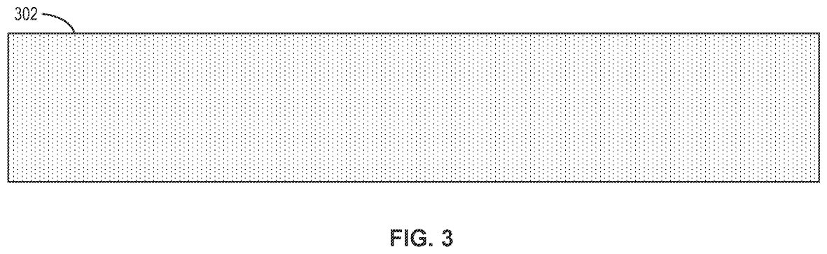

In some examples, an amount (e.g., a percent volume, a concentration) of the filler material 220 in the conductive material 216 can be adjusted to adjust a characteristic (e.g., the CTE) of the conductive material 216. For example, increasing the volume of the filler material 220 reduces the CTE of the conductive material 216 and, conversely, decreasing the volume of the filler material 220 increases the CTE of the conductive material 216. In some examples, the filler material 220 is at least 1% and up to 30% of the volume of the conductive material 216. As a result, the CTE of the conductive material 216 can be between 2 ppm/° C. and 16 ppm/° C. In some examples, by having a CTE substantially similar to that of the glass material of the glass core 206, the conductive material 216 expands and/or shrinks at a rate similar to that of the glass material when the glass core 206 is exposed to relatively high temperatures and/or relatively low temperatures. Accordingly, a likelihood of fracture, warpage, delamination, and/or other defects of the glass core 206 is reduced when a CTE differential (e.g., a difference between the CTE of the conductive material 216 and the CTE of the glass material) is reduced. In some examples, the glass core 206 can be manufactured as described in connection with FIGS. 3-7 below.

FIG. 3 is a side view of an example glass substrate (e.g., a glass panel) 302 used to produce the example glass core 206 of FIG. 2. In this example, the glass substrate 302 is fabricated from a glass material having a CTE of at least 3 ppm/° C. and up to 8 ppm/° C. The glass substrate 302 is produced as a single substrate in this example. However, the glass substrate 302 can include two or more substrates coupled together to produce the glass substrate 302.

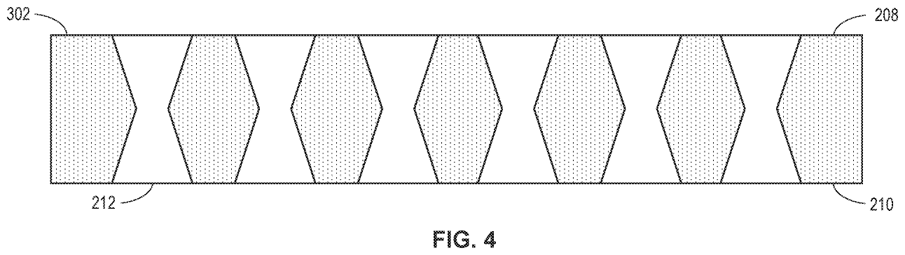

FIG. 4 illustrates the example vias 212 provided in the example glass substrate 302 of FIG. 3. In the illustrated example, the vias 212 are provided in the glass substrate 302 by etching and/or drilling into the first surface 208 and/or the second surface 210 of the glass substrate 302. In the illustrated example, the vias 212 are cylindrical and have a circular cross-sectional shape. In some examples, a different cross-sectional shape (e.g., square, hexagonal, elliptical, etc.) may be used instead. In this example, a cross-sectional diameter varies (e.g., increases and/or decreases) between the first and second surfaces 208, 210. In some examples, the cross-sectional diameter of the vias 212 is constant (e.g., not changing) between the first and second surfaces 208, 210. In some examples, the vias 212 are arranged in a two-dimensional array along the first and second surfaces 208, 210 of the glass substrate 302.

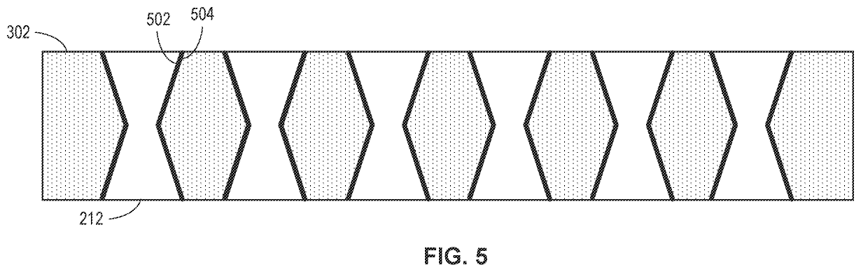

FIG. 5 illustrates an example adhesive layer (e.g., an adhesion promoter, an adhesive coating) 502 provided in the example vias 212 of the example glass substrate 302. In the illustrated example of FIG. 5, the adhesive layer 502 is provided (e.g., deposited, sputtered) on example sidewalls (e.g., inner surfaces) 504 of the vias 212. In some examples, depending on the deposition process, the adhesive layer 502 may also be applied to all exposed (e.g., exterior) surfaces of the glass substrate 302. In this example, the adhesive layer 502 includes silane (SiH₄), where the silane includes silicon and hydrogen. In some examples, one or more different materials may be included in the adhesive layer 502. In some examples, the adhesive layer 502 is provided to the vias 212 prior to the conductive material 216 being provided in the vias 212. In such examples, the adhesive layer 502 facilitates coupling of the conductive material 216 to the sidewalls 504 of the vias 212. In some examples, the adhesive layer 502 is not provided in the vias 212, such that the conductive material 216 is in direct contact (e.g., without an intervening layer) with the sidewalls 504.

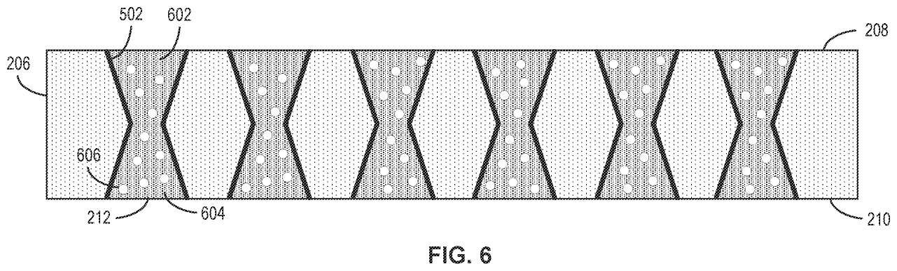

FIG. 6 illustrates a first example implementation of the glass core 206 of FIG. 2. In the illustrated example of FIG. 6, the glass core 206 includes a first example conductive material 602 provided to the vias 212, where the first conductive material 602 may be used for the conductive material 216 of FIG. 2. In this example, the first conductive material 602 is provided to the vias 212 as a copper paste including example copper (e.g., copper nanoparticles) 604 and example filler material (e.g., carbon nano tubes, ceramic fillers, diamond particles, metals, hollow fillers, clay fillers, and/or COFs) 606 dispersed in the copper paste. In some examples, traditional screen printing methods are used to produce pillars (e.g., conductive pillars) of the first conductive material 602. For example, the copper paste is deposited in the vias 212, and copper paste is hardened and/or cured to fabricate the pillars. In some examples, the copper paste can be hardened (e.g., solidified) by exposure to heat, pressure, air, light (e.g., UV light), etc. In some examples, the resulting first conductive material 602 has a CTE between 2 ppm/° C. and 16 ppm/° C. In some examples, the first conductive material 602 allows passage of electrical signals therethrough between the first and second surfaces 208, 210 of the glass core 206. While the adhesive layer 502 is included in the vias 212 in this example, the adhesive layer 502 may be omitted in some examples.

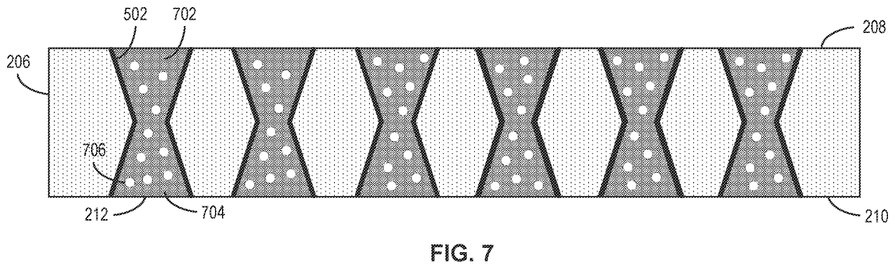

FIG. 7 illustrates a second example implementation of the glass core 206 of FIG. 2. In the illustrated example of FIG. 7, the glass core 206 includes a second example conductive material 702 provided to the vias 212, where the second conductive material 702 may be used for the conductive material 216 of FIG. 2 (e.g., in addition to or instead of the first conductive material of FIG. 6). In this example, the second conductive material 702 is provided to the vias 212 as an example gallium paste 704 including a filler material (e.g., carbon nano tubes, ceramic fillers, diamond particles, metals, hollow fillers, clay fillers, and/or COFs) 706 dispersed in the gallium paste 704. In some examples, the gallium paste 704 can include silver (e.g., silver particles), indium, tin, and/or zinc. In this example, the gallium paste 704 is deposited in the vias 212, and the gallium paste 704 is hardened and/or cured to fabricate pillars of the second conductive material 702. In some examples, the gallium paste 704 can be hardened (e.g., solidified) by exposure to heat, pressure, air, light (e.g., UV light), etc. In some examples, the resulting second conductive material 702 has a CTE between 3 ppm/° C. and 16 ppm/° C. In some examples, the second conductive material 702 allows passage of electrical signals therethrough between the first and second surfaces 208, 210 of the glass core 206. While the adhesive layer 502 is included in the vias 212 in this example, the adhesive layer 502 may be omitted in some examples.

In some examples, both of the first and second conductive materials 602, 702 may be used in the glass core 206. For example, the first conductive material 602 of FIG. 6 may be provided in a first portion of the vias 212, and the second conductive material 702 of FIG. 7 may be provided in a second portion of the vias 212 different from the first portion.

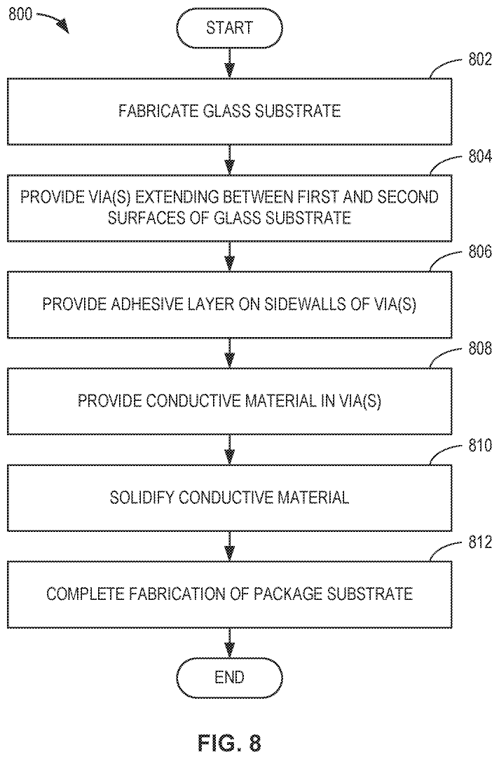

FIG. 8 is a flowchart representative of an example method 800 of manufacturing the example package substrate 110 of FIGS. 1 and/or 2 including the example glass core 206 of FIGS. 2, 6, and/or 7. In some examples, some or all of the operations outlined in the example method 800 are performed automatically by fabrication equipment that is programmed to perform the operations. Although the example method of manufacturing is described with reference to the flowchart illustrated in FIG. 8, many other methods may alternatively be used. For example, the order or execution of the blocks may be changed, and/or some of the blocks described may be combined, divided, re-arranged, omitted, eliminated, and/or implemented in any other way.

The example method 800 begins at block 802 by fabricating the example glass substrate 302 of FIG. 3. For example, the glass substrate 302 is fabricated from a glass material having a CTE of at least 3 ppm/° C. and up to 8 ppm/° C.

At block 804, the example method 800 includes providing the example vias 212 of FIG. 2 extending between the first and second example surfaces 208, 210 of the glass substrate 302. For example, the vias 212 are provided in the glass substrate 302 by etching and/or drilling into the first surface 208 and/or the second surface 210 of the glass substrate 302. In some examples, the vias 212 are provided having an hourglass shape and/or a cylindrical shape.

At block 806, the example method 800 includes providing the example adhesive layer 502 on the example sidewalls 504 of the vias 212. For example, the adhesive layer 502 is deposited and/or sputtered on the sidewalls 504 of the vias 212. In some examples, the adhesive layer 502 includes silane.

At block 808, the example method 800 includes providing the example conductive material 216 (e.g., the first conductive material 602 of FIG. 6 and/or the second conductive material 702 of FIG. 7) in the vias 212. For example, the conductive material 216 is provided (e.g., deposited) in the vias 212 as a metallic paste, where the metallic paste includes at least one of copper, gallium, or silver. In some examples, the metallic paste includes a filler material (e.g., the filler material 220 of FIG. 2) including at least one of carbon nano tubes, ceramic fillers, diamond particles, metals, clay fillers, or covalent organic frameworks dispersed in the metallic paste.

At block 810, the example method 800 includes solidifying the conductive material 216. For example, the metallic paste in the vias 212 is solidified (e.g., hardened, cured) to fabricate pillars made of the conductive material 216. In some examples, the metallic paste is solidified by exposure to heat, pressure, air, light (e.g., UV light), etc.

At block 812, the example method 800 includes completing fabrication of the example package substrate 110. For example, the first example build-up layers 202 are coupled to (e.g., deposited on) the first surface 208 of the glass core 206 and the second example build-up layers 204 are coupled to the second surface 210 of the glass core 206 to produce the example package substrate 110.

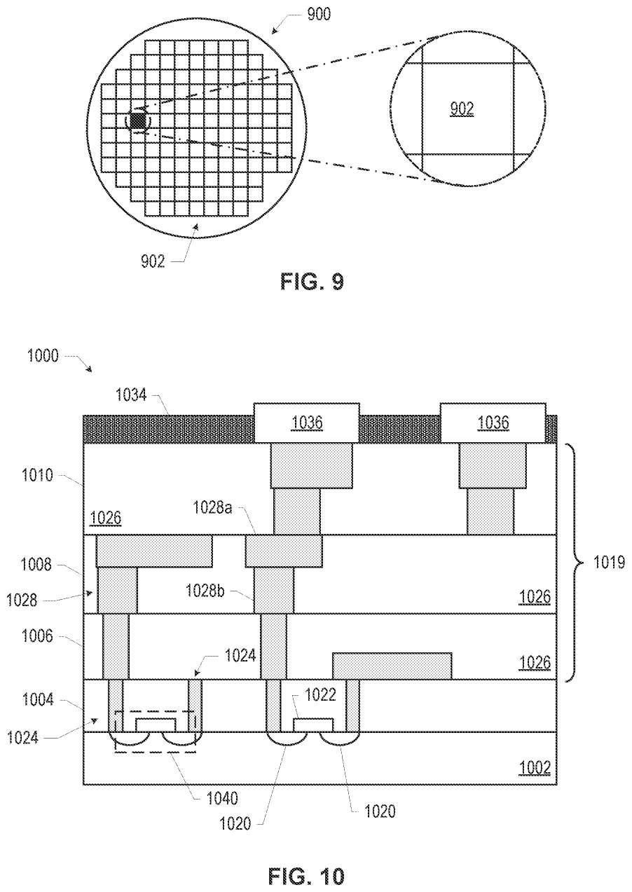

The example package substrate 110 including the example glass core 206 disclosed herein may be included in any suitable electronic component. FIGS. 9-13 illustrate various examples of apparatus that may include or be included in the package substrate 110 disclosed herein.

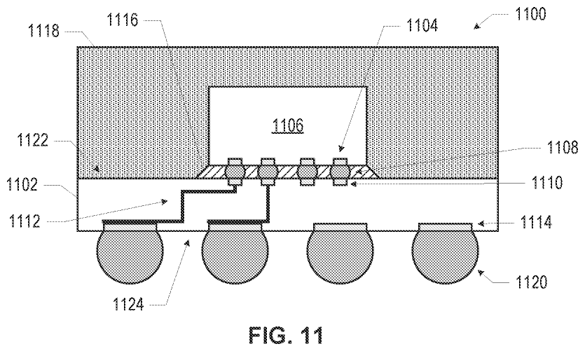

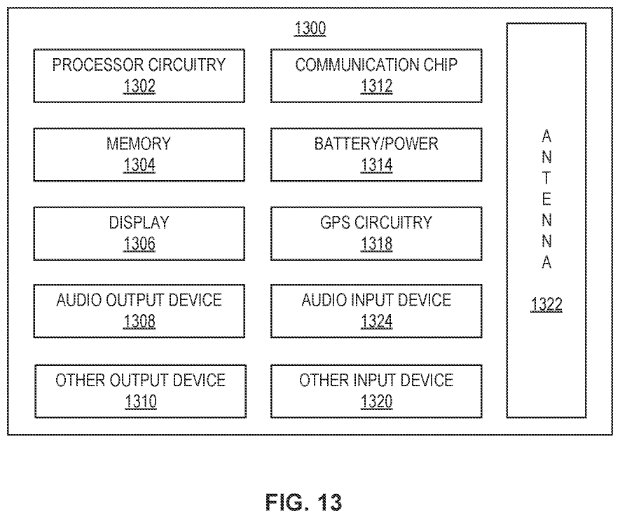

FIG. 9 is a top view of a wafer 900 and dies 902 that may be included in an IC package whose substrate includes one or more glass cores (e.g., as discussed below with reference to FIG. 11) in accordance with any of the examples disclosed herein. The wafer 900 may be composed of semiconductor material and may include one or more dies 902 having circuitry. Each of the dies 902 may be a repeating unit of a semiconductor product. After the fabrication of the semiconductor product is complete, the wafer 900 may undergo a singulation process in which the dies 902 are separated from one another to provide discrete “chips.” The die 902 may include one or more transistors (e.g., some of the transistors 1040 of FIG. 10, discussed below), supporting circuitry to route electrical signals to the transistors, passive components (e.g., traces, resistors, capacitors, inductors, and/or other circuitry), and/or any other components. In some examples, the die 902 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry. Multiple ones of these devices may be combined on a single die 902. For example, a memory array formed by multiple memory circuits may be formed on a same die 902 as programmable circuitry (e.g., the processor circuitry 1302 of FIG. 13) or other logic circuitry. Such memory may store information or instructions for use by the programmable circuitry. The example package substrate 110 disclosed herein may be manufactured using a die-to-wafer assembly technique in which some dies are attached to a wafer 900 that include others of the dies, and the wafer 900 is subsequently singulated.

FIG. 10 is a cross-sectional side view of an IC device 1000 that may be included in an IC package whose substrate includes one or more glass cores (e.g., as discussed below with reference to FIG. 11), in accordance with any of the examples disclosed herein. One or more of the IC devices 1000 may be included in one or more dies 902 (FIG. 9). The IC device 1000 may be formed on a die substrate 1002 (e.g., the wafer 900 of FIG. 9) and may be included in a die (e.g., the die 902 of FIG. 9). The die substrate 1002 may be a semiconductor substrate composed of semiconductor material systems including, for example, n-type or p-type materials systems (or a combination of both). The die substrate 1002 may include, for example, a crystalline substrate formed using a bulk silicon or a silicon-on-insulator (SOI) substructure. In some examples, the die substrate 1002 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 1002. Although a few examples of materials from which the die substrate 1002 may be formed are described here, any material that may serve as a foundation for an IC device 1000 may be used. The die substrate 1002 may be part of a singulated die (e.g., the dies 902 of FIG. 9) or a wafer (e.g., the wafer 900 of FIG. 9).

The IC device 1000 may include one or more device layers 1004 disposed on or above the die substrate 1002. The device layer 1004 may include features of one or more transistors 1040 (e.g., metal oxide semiconductor field-effect transistors (MOSFETs)) formed on the die substrate 1002. The device layer 1004 may include, for example, one or more source and/or drain (S/D) regions 1020, a gate 1022 to control current flow between the S/D regions 1020, and one or more S/D contacts 1024 to route electrical signals to/from the S/D regions 1020. The transistors 1040 may include additional features not depicted for the sake of clarity, such as device isolation regions, gate contacts, and the like. The transistors 1040 are not limited to the type and configuration depicted in FIG. 10 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1040 may include a gate 1022 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 1040 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some examples, when viewed as a cross-section of the transistor 1040 along the source-channel-drain direction, the gate electrode may consist of a U-shaped structure that includes a bottom portion substantially parallel to the surface of the die substrate 1002 and two sidewall portions that are substantially perpendicular to the top surface of the die substrate 1002. In other examples, at least one of the metal layers that form the gate electrode may simply be a planar layer that is substantially parallel to the top surface of the die substrate 1002 and does not include sidewall portions substantially perpendicular to the top surface of the die substrate 1002. In other examples, the gate electrode may consist of a combination of U-shaped structures and planar, non-U-shaped structures. For example, the gate electrode may consist of one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some examples, a plurality of spacer pairs may be used; for instance, two pairs, three pairs, or four pairs of sidewall spacers may be formed on opposing sides of the gate stack.

The S/D regions 1020 may be formed within the die substrate 1002 adjacent to the gate 1022 of each transistor 1040. The S/D regions 1020 may be formed using an implantation/diffusion process or an etching/deposition process, for example. In the former process, dopants such as boron, aluminum, antimony, phosphorous, or arsenic may be ion-implanted into the die substrate 1002 to form the S/D regions 1020. An annealing process that activates the dopants and causes them to diffuse farther into the die substrate 1002 may follow the ion-implantation process. In the latter process, the die substrate 1002 may first be etched to form recesses at the locations of the S/D regions 1020. An epitaxial deposition process may then be carried out to fill the recesses with material that is used to fabricate the S/D regions 1020. In some implementations, the S/D regions 1020 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 1020 may be formed using one or more alternate semiconductor materials such as germanium or a group III-V material or alloy. In further examples, one or more layers of metal and/or metal alloys may be used to form the S/D regions 1020.

Electrical signals, such as power and/or input/output (I/O) signals, may be routed to and/or from the devices (e.g., transistors 1040) of the device layer 1004 through one or more interconnect layers disposed on the device layer 1004 (illustrated in FIG. 10 as interconnect layers 1006-1010). For example, electrically conductive features of the device layer 1004 (e.g., the gate 1022 and the S/D contacts 1024) may be electrically coupled with the interconnect structures 1028 of the interconnect layers 1006-1010. The one or more interconnect layers 1006-1010 may form a metallization stack (also referred to as an “ILD stack”) 1019 of the IC device 1000.

The interconnect structures 1028 may be arranged within the interconnect layers 1006-1010 to route electrical signals according to a wide variety of designs (in particular, the arrangement is not limited to the particular configuration of interconnect structures 1028 depicted in FIG. 10). Although a particular number of interconnect layers 1006-1010 is depicted in FIG. 10, examples of the present disclosure include IC devices having more or fewer interconnect layers than depicted.

In some examples, the interconnect structures 1028 may include lines 1028a and/or vias 1028b filled with an electrically conductive material such as a metal. The lines 1028a may be arranged to route electrical signals in a direction of a plane that is substantially parallel with a surface of the die substrate 1002 upon which the device layer 1004 is formed. For example, the lines 1028a may route electrical signals in a direction in and out of the page from the perspective of FIG. 10. The vias 1028b may be arranged to route electrical signals in a direction of a plane that is substantially perpendicular to the surface of the die substrate 1002 upon which the device layer 1004 is formed. In some examples, the vias 1028b may electrically couple lines 1028a of different interconnect layers 1006-1010 together.

The interconnect layers 1006-1010 may include a dielectric material 1026 disposed between the interconnect structures 1028, as shown in FIG. 10. In some examples, the dielectric material 1026 disposed between the interconnect structures 1028 in different ones of the interconnect layers 1006-1010 may have different compositions; in other examples, the composition of the dielectric material 1026 between different interconnect layers 1006-1010 may be the same.

A first interconnect layer 1006 (referred to as Metal 1 or “M1”) may be formed directly on the device layer 1004. In some examples, the first interconnect layer 1006 may include lines 1028a and/or vias 1028b, as shown. The lines 1028a of the first interconnect layer 1006 may be coupled with contacts (e.g., the S/D contacts 1024) of the device layer 1004.

A second interconnect layer 1008 (referred to as Metal 2 or “M2”) may be formed directly on the first interconnect layer 1006. In some examples, the second interconnect layer 1008 may include vias 1028b to couple the lines 1028a of the second interconnect layer 1008 with the lines 1028a of the first interconnect layer 1006. Although the lines 1028a and the vias 1028b are structurally delineated with a line within each interconnect layer (e.g., within the second interconnect layer 1008) for the sake of clarity, the lines 1028a and the vias 1028b may be structurally and/or materially contiguous (e.g., simultaneously filled during a dual-damascene process) in some examples.

A third interconnect layer 1010 (referred to as Metal 3 or “M3”) (and additional interconnect layers, as desired) may be formed in succession on the second interconnect layer 1008 according to similar techniques and configurations described in connection with the second interconnect layer 1008 or the first interconnect layer 1006. In some examples, the interconnect layers that are “higher up” in the metallization stack 1019 in the IC device 1000 (i.e., further away from the device layer 1004) may be thicker.

The IC device 1000 may include a solder resist material 1034 (e.g., polyimide or similar material) and one or more conductive contacts 1036 formed on the interconnect layers 1006-1010. In FIG. 10, the conductive contacts 1036 are illustrated as taking the form of bond pads. The conductive contacts 1036 may be electrically coupled with the interconnect structures 1028 and configured to route the electrical signals of the transistor(s) 1040 to other external devices. For example, solder bonds may be formed on the one or more conductive contacts 1036 to mechanically and/or electrically couple a chip including the IC device 1000 with another component (e.g., a circuit board). The IC device 1000 may include additional or alternate structures to route the electrical signals from the interconnect layers 1006-1010; for example, the conductive contacts 1036 may include other analogous features (e.g., posts) that route the electrical signals to external components.

FIG. 11 is a cross-sectional view of an example IC package 1100 that may include one or more glass cores. The package substrate 1102 may be formed of a dielectric material, and may have conductive pathways extending through the dielectric material between upper and lower faces 1122, 1124, or between different locations on the upper face 1122, and/or between different locations on the lower face 1124. These conductive pathways may take the form of any of the interconnects 1028 discussed above with reference to FIG. 10. In some examples, any number of glass cores (with any suitable structure) may be included in a package substrate 1102. In some examples, no glass cores may be included in the package substrate 1102.

The IC package 1100 may include a die 1106 coupled to the package substrate 1102 via conductive contacts 1104 of the die 1106, first-level interconnects 1108, and conductive contacts 1110 of the package substrate 1102. The conductive contacts 1110 may be coupled to conductive pathways 1112 through the package substrate 1102, allowing circuitry within the die 1106 to electrically couple to various ones of the conductive contacts 1114 or to the glass cores (or to other devices included in the package substrate 1102, not shown). The first-level interconnects 1108 illustrated in FIG. 11 are solder bumps, but any suitable first-level interconnects 1108 may be used. As used herein, a “conductive contact” refers to a portion of conductive material (e.g., metal) serving as an electrical interface between different components. Conductive contacts may be recessed in, flush with, or extending away from a surface of a component, and may take any suitable form (e.g., a conductive pad or socket).

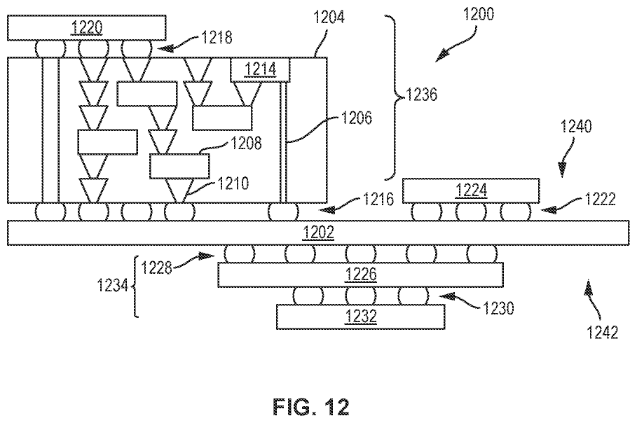

In some examples, an underfill material 1116 may be disposed between the die 1106 and the package substrate 1102 around the first-level interconnects 1108, and a mold compound 1118 may be disposed around the die 1106 and in contact with the package substrate 1102. In some examples, the underfill material 1116 may be the same as the mold compound 1118. Example materials that may be used for the underfill material 1116 and the mold compound 1118 are epoxy mold materials, as suitable. Second-level interconnects 1120 may be coupled to the conductive contacts 1114. The second-level interconnects 1120 illustrated in FIG. 11 are solder balls (e.g., for a ball grid array arrangement), but any suitable second-level interconnects 1120 may be used (e.g., pins in a pin grid array arrangement or lands in a land grid array arrangement). The second-level interconnects 1120 may be used to couple the IC package 1100 to another component, such as a circuit board (e.g., a motherboard), an interposer, or another IC package, as known in the art and as discussed below with reference to FIG. 12.

In FIG. 11, the IC package 1100 is a flip chip package, and includes a glass core in the package substrate 1102. The number and location of glass cores in the package substrate 1102 of the IC package 1100 is simply illustrative, and any number of glass cores (with any suitable structure) may be included in a package substrate 1102. In some examples, no glass core may be included in the package substrate 1102. The die 1106 may take the form of any of the examples of the die 1302 discussed herein (e.g., may include any of the examples of the IC device 1000). In some examples, the die 1106 may include one or more glass cores (e.g., as discussed above with reference to FIG. 9 and FIG. 10); in other examples, the die 1106 may not include any glass cores.

Although the IC package 1100 illustrated in FIG. 11 is a flip chip package, other package architectures may be used. For example, the IC package 1100 may be a ball grid array (BGA) package, such as an embedded wafer-level ball grid array (eWLB) package. In another example, the IC package 1100 may be a wafer-level chip scale package (WLCSP) or a panel fanout (FO) package. Although a single die 1106 is illustrated in the IC package 1100 of FIG. 11, an IC package 1100 may include multiple dies 1106 (e.g., with one or more of the multiple dies 1106 coupled to a glass core included in the package substrate 1102). An IC package 1100 may include additional passive components, such as surface-mount resistors, capacitors, and inductors disposed on the first face 1122 or the second face 1124 of the package substrate 1102. More generally, an IC package 1100 may include any other active or passive components known in the art.

FIG. 12 is a cross-sectional side view of an IC device assembly 1200 that may include the glass core disclosed herein. The IC device assembly 1200 includes a number of components disposed on a circuit board 1202 (which may be, for example, a motherboard). The IC device assembly 1200 includes components disposed on a first face 1240 of the circuit board 1202 and an opposing second face 1242 of the circuit board 1202; generally, components may be disposed on one or both faces 1240 and 1242.

In some examples, the circuit board 1202 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1202. In other examples, the circuit board 1202 may be a non-PCB substrate.

The IC device assembly 1200 illustrated in FIG. 12 includes a package-on-interposer structure 1236 coupled to the first face 1240 of the circuit board 1202 by coupling components 1216. The coupling components 1216 may electrically and mechanically couple the package-on-interposer structure 1236 to the circuit board 1202, and may include solder balls (as shown in FIG. 12), male and female portions of a socket, an adhesive, an underfill material, and/or any other suitable electrical and/or mechanical coupling structure.

The package-on-interposer structure 1236 may include an IC package 1220 coupled to an interposer 1204 by coupling components 1218. The coupling components 1218 may take any suitable form for the application, such as the forms discussed above with reference to the coupling components 1216. Although a single IC package 1220 is shown in FIG. 12, multiple IC packages may be coupled to the interposer 1204; indeed, additional interposers may be coupled to the interposer 1204. The interposer 1204 may provide an intervening substrate used to bridge the circuit board 1202 and the IC package 1220. The IC package 1220 may be or include, for example, a die (the die 902 of FIG. 9), an IC device (e.g., the IC device 1000 of FIG. 10), or any other suitable component. Generally, the interposer 1204 may spread a connection to a wider pitch or reroute a connection to a different connection. For example, the interposer 1204 may couple the IC package 1220 (e.g., a die) to a set of BGA conductive contacts of the coupling components 1216 for coupling to the circuit board 1202. In the example illustrated in FIG. 12, the IC package 1220 and the circuit board 1202 are attached to opposing sides of the interposer 1204; in other examples, the IC package 1220 and the circuit board 1202 may be attached to a same side of the interposer 1204. In some examples, three or more components may be interconnected by way of the interposer 1204.

In some examples, the interposer 1204 may be formed as a PCB, including multiple metal layers separated from one another by layers of dielectric material and interconnected by electrically conductive vias. In some examples, the interposer 1204 may be formed of an epoxy resin, a fiberglass-reinforced epoxy resin, an epoxy resin with inorganic fillers, a ceramic material, or a polymer material such as polyimide. In some examples, the interposer 1204 may be formed of alternate rigid or flexible materials that may include the same materials described above for use in a semiconductor substrate, such as silicon, germanium, and other group III-V and group IV materials. The interposer 1204 may include metal interconnects 1208 and vias 1210, including but not limited to through-silicon vias (TSVs) 1206. The interposer 1204 may further include embedded devices 1214, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1204. The package-on-interposer structure 1236 may take the form of any of the package-on-interposer structures known in the art.

The IC device assembly 1200 may include an IC package 1224 coupled to the first face 1240 of the circuit board 1202 by coupling components 1222. The coupling components 1222 may take the form of any of the examples discussed above with reference to the coupling components 1216, and the IC package 1224 may take the form of any of the examples discussed above with reference to the IC package 1220.

The IC device assembly 1200 illustrated in FIG. 12 includes a package-on-package structure 1234 coupled to the second face 1242 of the circuit board 1202 by coupling components 1228. The package-on-package structure 1234 may include a first IC package 1226 and a second IC package 1232 coupled together by coupling components 1230 such that the first IC package 1226 is disposed between the circuit board 1202 and the second IC package 1232. The coupling components 1228, 1230 may take the form of any of the examples of the coupling components 1216 discussed above, and the IC packages 1226, 1232 may take the form of any of the examples of the IC package 1220 discussed above. The package-on-package structure 1234 may be configured in accordance with any of the package-on-package structures known in the art.

FIG. 13 is a block diagram of an example electrical device 1300 that may include one or more of the example package substrate 110. For example, any suitable ones of the components of the electrical device 1300 may include one or more of the device assemblies 1200, IC devices 1000, or dies 902 disclosed herein, and may be arranged in the example package substrate 110. A number of components are illustrated in FIG. 13 as included in the electrical device 1300, but any one or more of these components may be omitted or duplicated, as suitable for the application. In some examples, some or all of the components included in the electrical device 1300 may be attached to one or more motherboards. In some examples, some or all of these components are fabricated onto a single system-on-a-chip (SoC) die.

Additionally, in various examples, the electrical device 1300 may not include one or more of the components illustrated in FIG. 13, but the electrical device 1300 may include interface circuitry for coupling to the one or more components. For example, the electrical device 1300 may not include a display 1306, but may include display interface circuitry (e.g., a connector and driver circuitry) to which a display 1306 may be coupled. In another set of examples, the electrical device 1300 may not include an audio input device 1324 (e.g., microphone) or an audio output device 1308 (e.g., a speaker, a headset, earbuds, etc.), but may include audio input or output device interface circuitry (e.g., connectors and supporting circuitry) to which an audio input device 1324 or audio output device 1308 may be coupled.

The electrical device 1300 may include programmable circuitry 1302 (e.g., one or more processing devices). The programmable circuitry 1302 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1300 may include a memory 1304, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1304 may include memory that shares a die with the programmable circuitry 1302. This memory may be used as cache memory and may include embedded dynamic random access memory (eDRAM) or spin transfer torque magnetic random access memory (STT-MRAM).

In some examples, the electrical device 1300 may include a communication chip 1312 (e.g., one or more communication chips). For example, the communication chip 1312 may be configured for managing wireless communications for the transfer of data to and from the electrical device 1300. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1312 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1312 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1312 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1312 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1312 may operate in accordance with other wireless protocols in other examples. The electrical device 1300 may include an antenna 1322 to facilitate wireless communications and/or to receive other wireless communications (such as AM or FM radio transmissions).

In some examples, the communication chip 1312 may manage wired communications, such as electrical, optical, or any other suitable communication protocols (e.g., the Ethernet). As noted above, the communication chip 1312 may include multiple communication chips. For instance, a first communication chip 1312 may be dedicated to shorter-range wireless communications such as Wi-Fi or Bluetooth, and a second communication chip 1312 may be dedicated to longer-range wireless communications such as global positioning system (GPS), EDGE, GPRS, CDMA, WiMAX, LTE, EV-DO, or others. In some examples, a first communication chip 1312 may be dedicated to wireless communications, and a second communication chip 1312 may be dedicated to wired communications.

The electrical device 1300 may include battery/power circuitry 1314. The battery/power circuitry 1314 may include one or more energy storage devices (e.g., batteries or capacitors) and/or circuitry for coupling components of the electrical device 1300 to an energy source separate from the electrical device 1300 (e.g., AC line power).

The electrical device 1300 may include a display 1306 (or corresponding interface circuitry, as discussed above). The display 1306 may include any visual indicators, such as a heads-up display, a computer monitor, a projector, a touchscreen display, a liquid crystal display (LCD), a light-emitting diode display, or a flat panel display.

The electrical device 1300 may include an audio output device 1308 (or corresponding interface circuitry, as discussed above). The audio output device 1308 may include any device that generates an audible indicator, such as speakers, headsets, or earbuds.

The electrical device 1300 may include an audio input device 1324 (or corresponding interface circuitry, as discussed above). The audio input device 1324 may include any device that generates a signal representative of a sound, such as microphones, microphone arrays, or digital instruments (e.g., instruments having a musical instrument digital interface (MIDI) output).

The electrical device 1300 may include a GPS circuitry 1318. The GPS circuitry 1318 may be in communication with a satellite-based system and may receive a location of the electrical device 1300, as known in the art.

The electrical device 1300 may include any other output device 1310 (or corresponding interface circuitry, as discussed above). Examples of the other output device 1310 may include an audio codec, a video codec, a printer, a wired or wireless transmitter for providing information to other devices, or an additional storage device.

The electrical device 1300 may include any other input device 1320 (or corresponding interface circuitry, as discussed above). Examples of the other input device 1320 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1300 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 1300 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements or method actions may be implemented by, e.g., the same entity or object. Additionally, although individual features may be included in different examples or claims, these may possibly be combined, and the inclusion in different examples or claims does not imply that a combination of features is not feasible and/or advantageous.

From the foregoing, it will be appreciated that example systems, methods, apparatus, and articles of manufacture have been disclosed that improve reliability of vias in a glass substrate of an IC package. An example glass substrate disclosed herein includes example conductive material provided in example vias extending between first and second surfaces of the glass substrate, where the conductive material includes a metal material and a filler material. In examples disclosed herein, the filler material has a CTE less than that of the metal material and can include one or more of carbon nano tubes, ceramic fillers, diamond particles, metals, clay fillers, or covalent organic frameworks. By including the filler material in the conductive material in the glass substrate, examples disclosed herein reduce a CTE differential between the conductive material of the vias and the glass substrate, thus reducing a likelihood of fracture, warpage, and/or other defects in the glass substrate when exposed to relatively high or low temperatures. Accordingly, disclosed systems, methods, apparatus, and articles of manufacture improve the efficiency of using a computing device by improving reliability of the glass substrate and/or the vias in subsequent assembly procedures of the IC package. Disclosed systems, methods, apparatus, and articles of manufacture are accordingly directed to one or more improvement(s) in the operation of a machine such as a computer or other electronic and/or mechanical device.

Example methods, systems, apparatus, and articles of manufacture to improve reliability of vias in a glass substrate of an IC package are disclosed herein. Further examples and combinations thereof include the following:

Example 1 includes an integrated circuit (IC) package substrate comprising a glass substrate, a via extending between first and second surfaces of the glass substrate, and a conductive material provided in the via, the conductive material including gallium and silver.

Example 2 includes the IC package substrate of example 1, wherein the via is hourglass shaped or cylindrical.

Example 3 includes the IC package substrate of example 1, further including a filler material in the conductive material.

Example 4 includes the IC package substrate of example 3, wherein the filler material has a negative coefficient of thermal expansion.

Example 5 includes the IC package substrate of example 1, wherein the conductive material includes at least one of indium, tin, or zinc.

Example 6 includes the IC package substrate of example 1, wherein the conductive material includes copper.

Example 7 includes the IC package substrate of example 3, wherein the filler material includes a carbon nano tube.

Example 8 includes the IC package substrate of example 3, wherein the filler material includes a ceramic filler.

Example 9 includes the IC package substrate of example 3, wherein the filler material includes a diamond particle.

Example 10 includes the IC package substrate of example 3, wherein the conductive material includes a first metal material, the filler material including a second metal material different from the first metal material.

Example 11 includes the IC package substrate of example 1, further including an adhesive layer provided in the via, the adhesive layer to coat an inner surface of the via.

Example 12 includes the IC package substrate of example 11, wherein the adhesive layer includes silicon and hydrogen.

Example 13 includes the IC package substrate of example 3, wherein the filler material is between 1 percent volume and 30 percent volume of the conductive material.

Example 14 includes the IC package substrate of example 3, wherein the conductive material has a first coefficient of thermal expansion, the filler material has a second coefficient of thermal expansion, the first coefficient of thermal expansion greater than the second coefficient of thermal expansion.

Example 15 includes the IC package substrate of example 14, wherein the first coefficient of thermal expansion is greater than zero and wherein the second coefficient of thermal expansion is less than zero.

Example 16 includes a glass core of an integrated circuit (IC) package substrate, the glass core comprising a first surface, a second surface opposite the first surface, and a conductive pillar extending between the first and second surfaces, the conductive pillar including gallium and silver.

Example 17 includes the glass core of example 16, wherein a diameter of the conductive pillar decreases from the first surface to a point between the first and second surfaces, the diameter of the conductive pillar to increase from the point to the second surface.

Example 18 includes the glass core of example 16, wherein the conductive pillar further includes a material having a negative coefficient of thermal expansion.

Example 19 includes a method to produce a glass core for a package substrate of an integrated circuit chip, the method comprising providing a via extending between first and second surfaces of the glass core, and providing a conductive material in the via, the conductive material including a gallium and silver.

Example 20 includes the method of example 19, wherein the conductive material further includes a filler material, and wherein providing the conductive material in the via includes depositing a metallic paste in the via, the metallic paste including the filler material, and applying heat to solidify the metallic paste.

The following claims are hereby incorporated into this Detailed Description by this reference. Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

What is claimed is:

1. An integrated circuit (IC) package substrate comprising:
a glass substrate;
a via extending between first and second surfaces of the glass substrate; and
a conductive material provided in the via, the conductive material including gallium and silver.

2. The IC package substrate of claim 1, wherein the via is hourglass shaped or cylindrical.

3. The IC package substrate of claim 1, further including a filler material in the conductive material.

4. The IC package substrate of claim 3, wherein the filler material has a negative coefficient of thermal expansion.

5. The IC package substrate of claim 1, wherein the conductive material includes at least one of indium, tin, or zinc.

6. The IC package substrate of claim 1, wherein the conductive material includes copper.

7. The IC package substrate of claim 3, wherein the filler material includes a carbon nano tube.

8. The IC package substrate of claim 3, wherein the filler material includes a ceramic filler.

9. The IC package substrate of claim 3, wherein the filler material includes a diamond particle.

10. The IC package substrate of claim 3, wherein the conductive material includes a first metal material, the filler material including a second metal material different from the first metal material.

11. The IC package substrate of claim 1, further including an adhesive layer provided in the via, the adhesive layer to coat an inner surface of the via.

12. The IC package substrate of claim 11, wherein the adhesive layer includes silicon and hydrogen.

13. The IC package substrate of claim 3, wherein the filler material is between 1 percent volume and 30 percent volume of the conductive material.

14. The IC package substrate of claim 3, wherein the conductive material has a first coefficient of thermal expansion, the filler material has a second coefficient of thermal expansion, the first coefficient of thermal expansion greater than the second coefficient of thermal expansion.

15. The IC package substrate of claim 14, wherein the first coefficient of thermal expansion is greater than zero and wherein the second coefficient of thermal expansion is less than zero.

16. A glass core of an integrated circuit (IC) package substrate, the glass core comprising:
a first surface;
a second surface opposite the first surface; and
a conductive pillar extending between the first and second surfaces, the conductive pillar including gallium and silver.

17. The glass core of claim 16, wherein a diameter of the conductive pillar decreases from the first surface to a point between the first and second surfaces, the diameter of the conductive pillar to increase from the point to the second surface.

18. The glass core of claim 16, wherein the conductive pillar further includes a material having a negative coefficient of thermal expansion.

19. A method to produce a glass core for a package substrate of an integrated circuit chip, the method comprising:
providing a via extending between first and second surfaces of the glass core; and
providing a conductive material in the via, the conductive material including a gallium and silver.

20. The method of claim 19, wherein the conductive material further includes a filler material, and wherein providing the conductive material in the via includes:
depositing a metallic paste in the via, the metallic paste including the filler material; and
applying heat to solidify the metallic paste.
